(19) United States
(12) Patent Application Publication
(10) Pub. No.: US 2003/0066015 A1
(43) Pub. Date: Apr. 3, 2003

(54) System for synchronising a multiple access digital telecommunication system

(76) Inventor: Philippe Sehier, Saint Germain En Laye (FR)

Correspondence Address: Sughrue Mion Zinn, Macpeak & Seas, Suite 800, 2100 Pennsylvania Avenue NW, Washington, DC, 20037-3213, US

(21) Appl. No.: 10/204,711

(22) PCT Filed: Feb. 22, 2001
(86) PCT No.: PCT/FR01/00518

(30) Foreign Application Priority Data
Feb. 24, 2000 (FR) 00/02325

(51) Int. Cl. H03M 13/00

(52) U.S. Cl. 714/774

(57) ABSTRACT

The invention concerns a method and a device for transmitting digital data. The device comprises means (12) for verifying the spectral efficacy of the transmission. The method consists in assigning to the digital data an error correcting code whereof the encoding rate is modifiable in accordance with the desired spectral efficacy. Preferably, the difference between successive encoding rate values is, at least for certain values, not more than 1/10. For example, a parity bit code and/or a repetitive code is used.

The present invention relates to a method and a system for transmitting digital information, for use in a multiple access telecommunication system, in particular when propagation conditions are variable.

Multiple access telecommunication systems include cellular telephone systems and satellite communication systems in which terminals communicate via a base station, for example.

In telecommunication systems using radio links, propagation conditions are generally variable. They depend in particular on atmospheric conditions, the position and the movement of a terminal (if the latter is mobile), and, in the case of a satellite telecommunication system, the position of the terminal in the area of vision of the satellite and the position of the satellite if it is not a geosynchronous satellite. In this case, the waveform of the signal, in particular the modulation, must preferably take account of changing propagation conditions.

Also, a base station usually communicates with terminals that can send at different powers and over paths with different propagation conditions. A transmitter is principally characterized by its equivalent isotropic radiated power (EIRP), which is the product of the power of its amplifier by the gain of its antenna.

The continuing increase in the quantity of information to be transmitted imposes optimum use of the frequency band allocated to each operator. In other words, it is preferable to optimize spectral efficiency, defined as the number of bits transmitted per unit time (second) and per unit frequency (Hertz). It is preferable for this optimization to be effected continuously, in other words that it be able to adapt to changing conditions, such as the propagation conditions or the power of the terminals.

To this end, it has already been proposed to modify the coding rate of an error corrector code as a function of the power of an information transmitter.

The invention stems from the realization that prior art methods do not really optimize the spectral efficiency continuously and/or minimize the error rate or packet loss rate. Also, the prior art method is complex.

The invention calls on simple technologies and optimizes spectral efficiency and/or performance continuously.

The transmission method according to the invention is characterized in that the digital data to be transmitted is assigned an error corrector code whose coding rate is determined by the associated receiver as a function of the power received from the transmitter and the difference between at least some successive values of the coding rate is, starting from unity, at most 1/10.

Choosing a coding rate varying in small steps optimizes performance, in other words the spectral efficiency and/or the error rate or packet loss rate, at all times.

The preferred embodiment of the invention uses a parity bit code and/or a repetition code and the coding rate of the parity bit code and/or the distribution factor is or are chosen as a function of the required coding rate.

The coding rate is the ratio between the number of incoming bits and the number of outgoing bits. For example, if a parity code adds one bit to every n information bits, the coding rate is n/(n+1).

Accordingly, one embodiment uses parity coding. In this case, the coding rate can take several values from 1/2 to 1.

To obtain a coding rate less than 1/2, the parity code is preferably combined with a repetition code. A repetition code simply repeats each bit at least once.

In this case, if the parity code rate is n/(n+1), the combination of the parity code with a repetition code produces a coding rate equal to n/(p(n+1)), where 1/p is the coding rate of the repetition code, and p is the number of repetitions of each bit.

Although using a parity code and/or a repetition code is preferred, as it yields a simple embodiment, the invention is naturally not limited to the use of these codes. Other codes can be used to vary the spectral efficiency, such as turbo codes (also known as product codes), convolutional codes, and block codes, and these codes can be punctured.

Note that, to vary the spectral efficiency and optimize transmission, the invention uses a technology known in the art, generally a simple technology. Simplification is all the more important if transmission uses an error corrector code and the invention uses the error corrector code to vary the spectral efficiency.

The error corrector code used to vary the spectral efficiency and/or to optimize performance may be sufficient to protect transmission against transmission errors. It may also be necessary to reinforce the error corrector code with another corrector code on the upstream side (on transmission), which for this reason is referred to as an “external code”.

The time division multiple access (TDMA) transmission technique is preferably used.

Whichever error corrector code is used, it is found that a high coding rate corresponds to a short transmission time. The high coding rate is used when a relatively high power (or EIRP) is available. A low coding rate has the drawback of a long transmission time, but can be used when the available power (or EIRP) is low.

Variable rate error coding is preferably combined with modulation to minimize envelope fluctuations such as minimum shift keying (MSK) modulation, which is a constant envelope frequency modulation. GMSK modulation can also be used, which is MSK modulation combined with Gaussian phase filtering to reduce the spacing between carriers by reducing the height of secondary lobes.

If MSK or GMSK modulation is used, the output offset of the amplifier is 0 dB, which ensures optimum use of the amplifier. The output offset of an amplifier is the offset relative to the saturation power, defined as 10log Pₛₐₜ/Pₘ, where Pₛₐₜ is the saturation power and Pₘ is the output power for an input signal of given level. This offset means that the transmit amplifiers operate in a virtually linear manner with minimum signal distortion.

Quadrature phase shift keying (QPSK) or offset QPSK (OQPSK) modulation can also be used, the latter modulation consisting of offsetting the in-phase and quadrature channels by half a symbol period to minimize amplitude modulation. In this case, the output offset is around 2 dB.

The invention relates generally to a method of transmitting digital information characterized in that the digital data to be transmitted is assigned an error corrector code whose coding rate is determined by the associated receiver as a function of the power received from the transmitter and the difference between at least some successive values of the coding rate is, starting from unity, at most 1/10.

The error corrector code is preferably chosen from the group comprising block codes and convolutional codes, which codes can be punctured and/or concatenated.

A parity bit code and/or a repetition code is preferably used. In this case, the coding rate of the parity bit code and/or the repetition factor is or are advantageously chosen as a function of the required coding rate.

For transmission, the coded digital data is preferably phase modulated, the modulation advantageously minimizing envelope fluctuations.

For reception of digital information transmitted by the method in which a parity bit code and/or a repetition code is used, decoding comprises, in one embodiment, and in series, repetition coded signal decoding followed by parity bit coded signal decoding.

In this case, the synchronization signals are preferably extracted from the decoded signals that were coded with a repetition code.

The coded data is interleaved, for example.

In one embodiment, the timing of the transmission of symbols is constant and independent of the coding rate.

If the transmitter is part of a multipoint-to-point or point-to-multipoint telecommunication system, access of the transmitter to the receiver is obtained on a time-sharing basis, for example.

The invention applies to a cellular telecommunication system in which each terminal sends to a base station and receives its signals from a base station, especially when the terminals have different powers and/or when propagation conditions between the base stations and the terminals are variable.

The invention also relates to a digital information transmission system employing the method described above.

Other features and advantages of the invention will become apparent in the course of the description of embodiments of the invention given with reference to the accompanying drawings, in which:

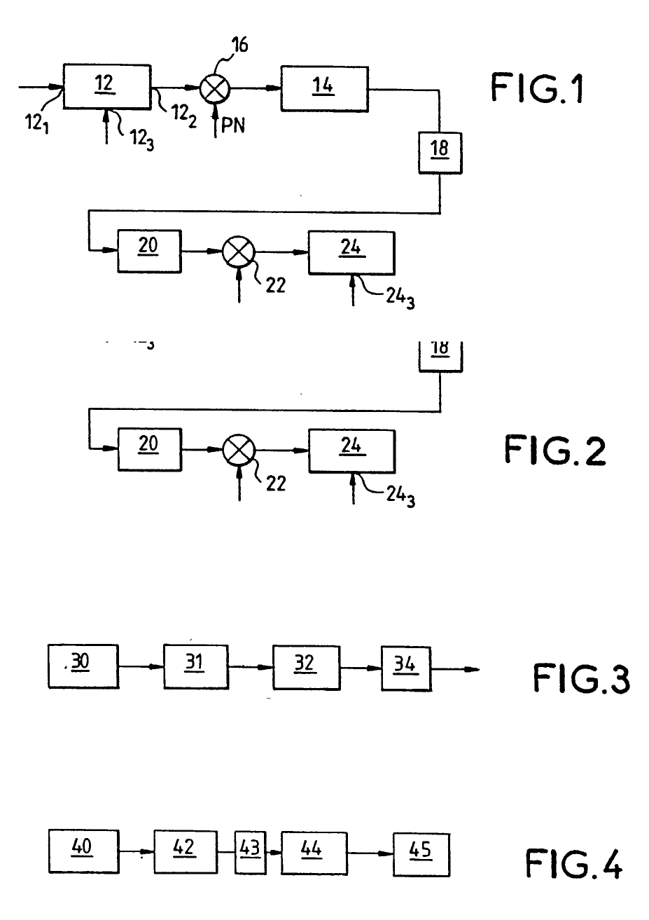

FIG. 1 is a diagram of digital packets transmitted by a transmitter according to the invention,

FIG. 2 is a diagram of a telecommunication system according to the invention,

FIG. 3 is a diagram of a transmitter according to the invention, and

FIG. 4 is a diagram of a receiver according to the invention.

The example described with reference to the figures concerns a satellite telecommunication system in which a large portion of the surface of the terrestrial globe is divided into areas, for example circular areas with a diameter of several hundred kilometers, and each area is allocated a base station or management stations, sometimes called a gateway. Terminals communicate via a non-geosynchronous satellite. Accordingly, a terminal calling another terminal in the same area or in a different area or a terminal connected to another telecommunication system transmits its signals to the base station via the satellite, and the base station forwards the signals to the destination terminal via a network.

In this telecommunication system, the terminals are of two types, namely domestic terminals, intended in particular for use by private individuals, and professional terminals. Domestic terminals have a low transmission power (or EIRP) and a low receive power but professional terminals have significantly higher transmit and receive powers. Given that all calls pass through the base station and that the terminals naturally have a limited power, the base station determines continuously the characteristics of the calls transmitted by each terminal. These characteristics are determined to maximize the transmission capacity of the system.

Thus, in accordance with the invention, the base station adjusts the spectral efficiency of each terminal as a function of its power or EIRP (equivalent isotropic radiated power). For example, professional terminals have a spectral efficiency of one bit per second per hertz whereas domestic terminals have a lower spectral efficiency, depending on their power or EIRP.

Hereinafter, for simplicity, the term “power” is used interchangeably to refer to the power as such or to the EIRP.

To adjust the spectral efficiency, the digital signals transmitted by each terminal are allocated an error corrector code whose coding rate varies as a function of the required spectral efficiency.

The coding rate of an error corrector code is the ratio between the number of incoming bits and the number of outgoing bits. The ratio is therefore less than 1 (one). Obviously transmission with no corrector code, whose coding rate is 1, will be the fastest, the symbols all being transmitted at the same rhythm, while calls transmitted with a coding rate less than 1 will be slower in proportion to the low value of the coding rate.

In other words, for the lower power terminals, the payload information transmission time will be longer than that for the higher power terminals, but the lower power terminals will be better protected against transmission errors.

The FIG. 1 diagram shows the transmission of packets on a given carrier. The packets, which correspond to different terminals T₁, T₂, T₃, are time-division multiplexed for transmission.

In this example, a terminal T₁ transmits two packets P₁ and P′₁, a terminal T₂ transmits a packet P₂, and a terminal T₃ transmits two packets P₃ and P′₃.

The packets transmitted by different terminals are separated by guard times τ such that there are no collisions between packets, even in the worst case desynchronization scenario.

In the example, the terminal T₁ has a favorable link balance, and can therefore use a high coding rate coding configuration, and thus a short transmission time for each packet. Conversely, the terminal T₃ has an unfavorable link balance and takes longer to transmit each packet.

The central station allocates transmission times, periods and configurations. In reserved mode (set up call), the transmission configurations (in particular the coding rate) are determined individually for each terminal as a function of information supplied by power monitoring means or more generally by radio resource management means.

The allocation information is transmitted to the terminals on a signaling channel.

In random access mode, which is used in particular to access the terminal when it is registered (i.e. when it is first installed on the network, or more generally if it has to reregister, for example following an incident), the central station reserves a number of time slots. The position in the frame and the transmission characteristics are transmitted to the terminals on a broadcast signaling channel.

FIG. 2 shows a diagram of the principle of transmitting signals from a terminal to the base station.

The terminal includes a coder 12 which applies an error corrector code to the input signals. It therefore converts the digital data applied to its input 12₁ into digital data appearing at its output 12₂. The output data has a number of bits greater than the number of input bits. If the number of bits applied to the input 12₁ is n and the number of bits appearing at the output 12₂ is n+k, the coding rate is n/(n+k).

The coding rate can be varied by control signals applied to an input 12₃ of the coder 12. In this example, the control signals are supplied by the base station.

The output signals of the coder 12 are transmitted to the input of a modulator 14, for example an OQPSK modulator.

A pseudo-noise generator 16 applies pseudo-noise to the coded signals before they are modulated. The generator superposes on the signals transmitted a pseudo-random sequence characteristic of the area concerned, which limits interference between adjacent areas. The signals leaving the modulator are then transmitted by the transmission channel 18 (including a non-geosynchronous satellite in this example).

The base station includes demodulation and synchronization means 20, a pseudo-noise generator 22 applying the sequence that is the inverse of that applied by the generator 16, and a decoder 24 which receives at an input 24₃ the same coding rate information as is applied to the input 12₃ of the coder 12.

The demodulator 20 includes a Nyquist filter, baseband transposer means, and sampler means.

The error corrector codes that can be used are block codes, convolutional codes, punctured codes, and concatenation codes.

A punctured code is a basic code with a low coding rate which is punctured by eliminating some redundant bits as a function of the required coding rate.

In the preferred embodiment of the invention, parity codes and repetition codes are used, and codes obtained by concatenating codes of these two types.

Accordingly, in one example which optimizes the distribution of coding rate values:

A coding rate (spectral efficiency) of 1 is obtained without error corrector coding.

A coding rate of 11/12 is obtained with a code adding one parity bit after 11 bits.

Similarly, a rate of 10/12 is obtained with a 5/6 parity code.

A rate of 9/12 is obtained with a 3/4 parity code.

A coding rate of 8/12 is obtained with a 2/3 parity code.

A coding rate of 6/12 is obtained with a repetition code in which each bit is repeated once.

A coding rate of 5/12 is obtained by concatenating a 5/6 parity code and a factor 2 repetition code (only one repetition).

A coding rate of 4/12 is obtained with a factor 3 repetition code, in which each bit is repeated twice.

Finally, a coding rate of 3/12 is obtained with a factor 4 repetition code (each bit is repeated three times).

To obtain finer steps between successive coding rates, other concatenations of parity codes and repetition codes can be used. For example, a coding rate of 5.5/12 is obtained by concatenating a factor 2 repetition code and an 11/12 parity code, and a coding rate of 4.5/12 is obtained by concatenating a factor 2 repetition code and a 3/4 parity code. Finally, a coding rate of 3.5/12 is obtained by concatenating a factor 2 repetition code and a 7/12 parity code.

The quantizing scale of the values and therefore of the steps is the result of a compromise between required performance and complexity. To reduce complexity, eliminating the 7/12 coding, which is not a parity code, and therefore gives rise to specific decoding problems, can be envisaged. The admissibility of the performance degradation to which the simplification leads is a function of the probability of each coding configuration appearing, and must be analyzed on an individual basis.

FIG. 3 shows a terminal using concatenation of a parity code and a repetition code.

Thus the transmitter part of the terminal includes an external coder 30 whose output is connected to the input of an interleaver 31 connected to the input of a parity coder 32 which delivers its signals to the input of a repetition coder 34. The signals from the coder 34 are transmitted to the modulator 14. The signal is then transmitted on the radio channel 18. The radio channel introduces a time-delay, a phase rotation and a frequency shift into the signal.

The purpose of the external coder 30 is to reinforce the error corrector coding if that provided by the coders 32 and 34 would be insufficient.

FIG. 4 shows the receiver part, which is in the base station in this example. The receiver part includes a QPSK demodulator 40 whose output is connected to the input of a repetition code decoder 42 delivering its signals to an internal code, e.g. parity code, decoder 44. The output of the decoder 44 is connected to the input of an interleaving system and then to an external decoder 45.

In this example, phase and frequency recovery 43 is effected between the output of the repetition code decoder 42 and the input of the parity code decoder 44.

This enables the phase recovery system to operate on the symbols whose signal/noise ratio is increased by the processing gain of the repetition code, i.e. with a gain of 10.logn dB, where n is the number of repetitions. This improves the performance of the phase recovery system.

The following considerations are also useful for a good understanding of the features and advantages of the invention:

The power used by a transmitter for a given call can be expressed in the following form:

$${P}_{e} = A \cdot {γ}_{b} ( r ) \cdot r \cdot M \cdot \frac{{N}_{o}}{{T}_{c}} \qquad ( 1 )$$

where:

Pₑ is the transmitted power,

A is the product of the gain and attenuation of the signal between the transmitter and the receiver,

γ_{b}(r) is the ratio at the operating point between the energy per information bit and the power density of thermal noise and interference,

r is the global coding rate,

M is the number of bits per symbol (so that 2^{M} is the number of states of the constellation),

Nₒ is the density of thermal noise and interference, and

T_{C} is the duration of the modulated symbols, or the “chip” in a spread spectrum system.

In accordance with the invention, the coding rate r is the product of three terms:

r=r_{fixed}·r_{variable}·rᵣₑₚₑₜᵢₜᵢₒₙ

the first term (r_{fixed}) relates to the code which does not participate in the variation of the rate (a turbo code in this example),

the second term (r_{variable}) contributes to fine adjustment of spectral efficiency (but within a limited range), and

the third term (rᵣₑₚₑₜᵢₜᵢₒₙ) provides coarse stepwise adjustments (1/2, 1/3, 1/4, etc.) but with a good dynamic.

γ_{b}(r), which is the ratio between the energy per bit and the noise power density, represents the value necessary to obtain the necessary quality in terms of error rate and/or packet loss rate (i.e. the required operating point in general), for a coding scheme with coding rate r.

This is because the operating point is generally a function of the coding scheme concerned. However, in a coding scheme that is correct, this value does not depend greatly on the coding rate. It is even possible to obtain lower operating points when the rate is low.

The operating point for a repetition code is completely independent of the number of repetitions. In accordance with the invention, the operating point is quasi constant throughout the range of variation of the coding rate.

Equation (1) above therefore shows clearly that reducing the coding rate reduces the power transmitted (all other terms remaining the same).

In one embodiment, the error corrector code is decoded with the aid of a soft in soft out (SISO) algorithm. The algorithm accepts at its input and produces at its output weighted values, i.e. values with amplitudes proportional to the reliability of the associated bit. This method, enabling the external code to operate with weighted values at its input, achieves an improvement in performance over a decoding algorithm producing firm decisions. The algorithm is, for example, that described in the paper “Optimal Decoding of Linear Codes For Minimizing Symbol Error Rate” by L. R. Bahl, J. Coke, F. Jelinek and J. Raviv published in IEEE transactions on Information Theory, March 1974, or a heuristic search algorithm. If internal parity and repetition codes are used, implementing these algorithms presents no particular difficulty, the internal codes being short.

The interleaving system 31 between the external coder and the internal coder (FIG. 3) at the transmission end and the deinterleaving system between the internal decoder and the external decoder at the receiving end are used to decorrelate the weighted values produced by the internal decoder. These systems aim to improve performance in terms of the error rate of the external code. It is known that the interleaving algorithm used and its parameters depend on the type of external code used; the choice of an algorithm and its parameter values is the result of a compromise between the improvement in performance and the resulting time-delay.

In other words, the transmission channel supplies variable coding rate (parity code and repetition code) weighted inputs to the input of the internal decoder. The variable coding rate internal decoder supplies weighted outputs that are applied through a deinterleaving system to the input of the fixed coding rate external decoder. Thus the fixed coding rate external decoder operates with weighted inputs and thus under optimum conditions.

1. A method of transmitting digital information, characterized in that the digital data to be transmitted is assigned an error corrector code whose coding rate is determined by the associated receiver as a function of the power received from the transmitter, in that the difference between at least some successive values of the coding rate is, starting from unity, at most 1/10, and in that the coding rate is preferably a function of the required spectral efficiency.

2. A method according to claim 1, characterized in that the error correcting code is chosen from the group comprising block codes and convolutional blocks [sic].

3. A method according to claim 2, characterized in that the codes are punctured and/or concatenated.

4. A method according to claim 2 or claim 3, characterized in that it uses a parity bit code and/or a repetition code.

5. A method according to claim 4, characterized in that the coding rate of the parity bit code and/or the repetition factor is or are chosen as a function of the required coding rate.

6. A method according to any preceding claim, characterized in that the coded digital data is phase modulated for transmission and the modulation preferably minimizes envelope fluctuations.

7. A method of receiving digital information transmitted by the method according to claim 4, characterized in that it includes, in series, decoding repetition coded signals followed by decoding signals coded with parity bits.

8. A method according to claim 7, characterized in that the synchronization signals are extracted from the decoded signals that were coded using a repetition code.

9. A method according to any preceding claim, characterized in that the coded data is interleaved.

10. A method according to any preceding claim, characterized in that the rhythm of the transmission of symbols is constant and independent of the coding rate.

11. A method according to any preceding claim, characterized in that the transmitter is part of a multipoint-to-point or point-to-multipoint telecommunication system and access of the transmitter to the receiver is on a time sharing basis.

12. Application of the method according to any preceding claim to a cellular telecommunication system in which each terminal sends to a base station and receives its signals from a base station.

13. A system according to claim 12, characterized in that it includes terminals with different powers.

14. A system according to claim 12 or claim 13, characterized in that the propagation conditions between the base station and the terminals are variable.

15. A system for transmitting digital information, characterized in that it includes means (12) for varying the spectral efficiency of transmission, including means for assigning the digital data an error corrector code whose coding rate is modifiable as a function of the required spectral efficiency, said code being such that the difference between at least some successive values of the coding rate, starting from unity, is at most 1/10, the coding rate of the transmitter being determined by the associated receiver as a function of the power received from the transmitter.

16. A system according to claim 15, characterized in that the error corrector code is chosen from the group comprising block codes and convolutional blocks [sic].

17. A system according to claim 16, characterized in that the codes are punctured and/or concatenated.

18. A system according to claim 16 or claim 17, characterized in that it uses a parity bit code and/or a repetition code.

19. A system according to claim 18, characterized in that the coding rate of the parity bit code and/or the repetition factor is or are chosen as a function of the required coding rate.

20. A system according to any of claims 15 to 19, characterized in that it includes a phase modulator for modulating the coded digital data for transmission and said modulator preferably applies a modulation that minimizes envelope fluctuations.

21. A system according to any of claims 15 to 20, characterized in that the coded data is interleaved.

22. A system according to any of claims 15 to 24 [sic], characterized in that the timing of the transmission of the symbols is constant and independent of the coding rate.

23. A system according to any of claims 15 to 22, characterized in that, being part of a multipoint-to-point or point-to-multipoint telecommunication system, access of the transmitter to the receiver is on a time sharing basis.

24. A system for receiving digital information transmitted by the method according to claim 4, characterized in that it includes, in series, a repetition coded signal decoder followed by a parity bit coded signal decoder.

25. A system according to claim 24, characterized in that the synchronization signals are extracted from the repetition coded signal decoder.
